(19) United States
(12) Patent Application Publication
(10) Pub. No.: US 2008/0299777 A1
(43) Pub. Date: Dec. 4, 2008

(54) Silicon nitride film dry etching method

(75) Inventor: Hisao Tosaka, Hachioji-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co.,Ltd., Tokyo (JP)

(21) Appl. No.: 12/154,946

(22) Filed: May 28, 2008

(30) Foreign Application Priority Data
May 30, 2007 (JP) 2007-143026

(51) Int. Cl. H01L 21/3065

(52) U.S. Cl. 438/724; 257/E21.218

(57) ABSTRACT

A silicon nitride film is dry etched by reactive ion etching using a mixed gas including a fluorine gas and an oxygen gas.

### CROSS-REFERENCE TO RELATED APPLICATIONS

This application is based upon and claims the benefit of priority from prior Japanese Patent Application No. 2007-143026, filed May 30, 2007, the entire contents of which are incorporated herein by reference.

### BACKGROUND OF THE INVENTION

1. Field of the Invention

The present invention relates to a method for dry etching a silicon nitride film.

2. Description of the Related Art

For example, there is a conventional thin film transistor of an inversely staggered type and of a channel protective film type (e.g., Jpn. Pat. Appln. KOKAI Publication No. 11-274143). In order to form the channel protective film, a channel protective film formation film made of silicon nitride is first formed on the upper surface of a formed intrinsic amorphous silicon film. Then, a resist film is formed and on the upper surface of the channel protective film formation film. Then, a mixed gas of a sulfur hexafluoride (SF₆) gas and an oxygen gas is used as an etching gas to remove parts of the channel protective film formation film except for a part in the region under the resist film, by dry etching, such that a channel protective film is formed under the resist film.

SF₆ in the etching gas used in such a dry etching method has recently been regarded as a problem to contribute to global warming, and it is therefore a critical issue to select an alternative gas.

### BRIEF SUMMARY OF THE INVENTION

It is therefore a principle object of the present invention to provide a silicon nitride film dry etching method capable of performing satisfactory dry etching of a silicon nitride film without using a gas such as SF₆ which contributes to global warming.

A preferred aspect of this invention is a silicon nitride film dry etching method comprising subjecting a silicon nitride film to dry etching by reactive ion etching using a mixed gas including a fluorine gas and an oxygen gas.

Another preferred aspect of this invention is a silicon nitride film dry etching method comprising: preparing a processing target material in which a silicon nitride film is provided on a substrate; carrying the processing target material into a chamber of a parallel plate type dry etching apparatus in which a high-frequency electrode and an opposite electrode are arranged in parallel with each other, and mounting the substrate of the processing target material on the high-frequency electrode; reducing the pressure in the chamber, and introducing a fluorine gas and an oxygen gas into the chamber; and applying high-frequency waves to the high-frequency electrode to etch the silicon nitride film in the chamber.

### BRIEF DESCRIPTION OF THE SEVERAL VIEWS OF THE DRAWING

FIG. 1 is a sectional view of one example of a part of a thin film transistor panel manufactured by a manufacturing method including a dry etching method of the present invention;

FIG. 2 is a sectional view of an initial step in one example of a method of manufacturing a thin film transistor panel shown in FIG. 1;

FIG. 3 is a sectional view of a step following FIG. 2;

FIG. 4 is a sectional view of a step following FIG. 3;

FIG. 5 is a sectional view of a step following FIG. 4;

FIG. 6 is a sectional view of a step following FIG. 5; and

FIG. 7 is a schematic configuration diagram of one example of an RIE apparatus.

### DETAILED DESCRIPTION OF THE INVENTION

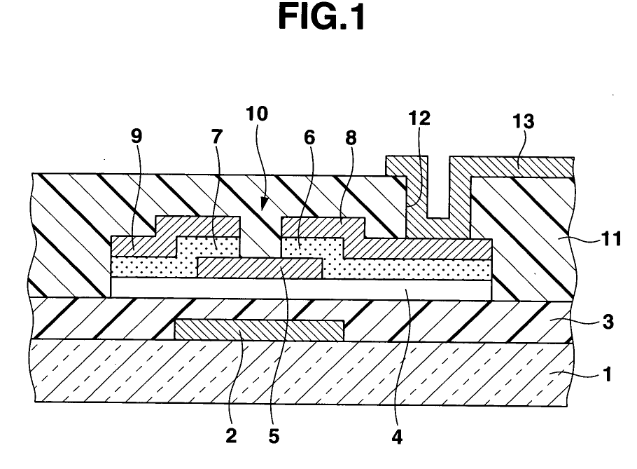

FIG. 1 is a sectional view for partially showing one example of a thin film transistor panel manufactured by a manufacturing method including a dry etching method of the present invention. This thin film transistor panel comprises a glass substrate 1. A gate electrode 2 made of, for example, chromium is provided in a predetermined place on the upper surface of the glass substrate 1. A gate insulating film 3 made of silicon nitride is provided on the upper surfaces of the gate electrode 2 and the glass substrate 1.

A semiconductor thin film 4 made of, for example, intrinsic amorphous silicon is provided in a predetermined place on the upper surface of the gate insulating film 3 above the gate electrode 2. A channel protective film 5 made of silicon nitride is provided on a part of the upper surface of the semiconductor thin film 4 to face the gate electrode 2. Ohmic contact layers 6, 7 made of n-type amorphous silicon are provided on both sides of the upper surface of the channel protective film 5 and on the upper surface of the semiconductor thin film 4 on both sides of the channel protective film 5. A source electrode 8 and a drain electrode 9 made of, for example, chromium are provided on the upper surfaces of the ohmic contact layers 6, 7, respectively.

Each of a plurality thin film transistors 10 of an inversely staggered type and of a channel protective film type is constituted by the gate electrode 2, the gate insulating film 3, the semiconductor thin film 4, the channel protective film 5, the ohmic contact layers 6, 7, the source electrode 8 and the drain electrode 9.

An overcoat film 11 made of silicon nitride is provided on the upper surfaces of the thin film transistors 10 and the gate insulating film 3. A contact hole 12 is provided in part of the overcoat film 11 corresponding to a predetermined place of the source electrode 8. A pixel electrode 13 made of ITO is provided in a predetermined place of the upper surface of the overcoat film 11 so that it is electrically connected to the source electrode 8 via the contact hole 12.

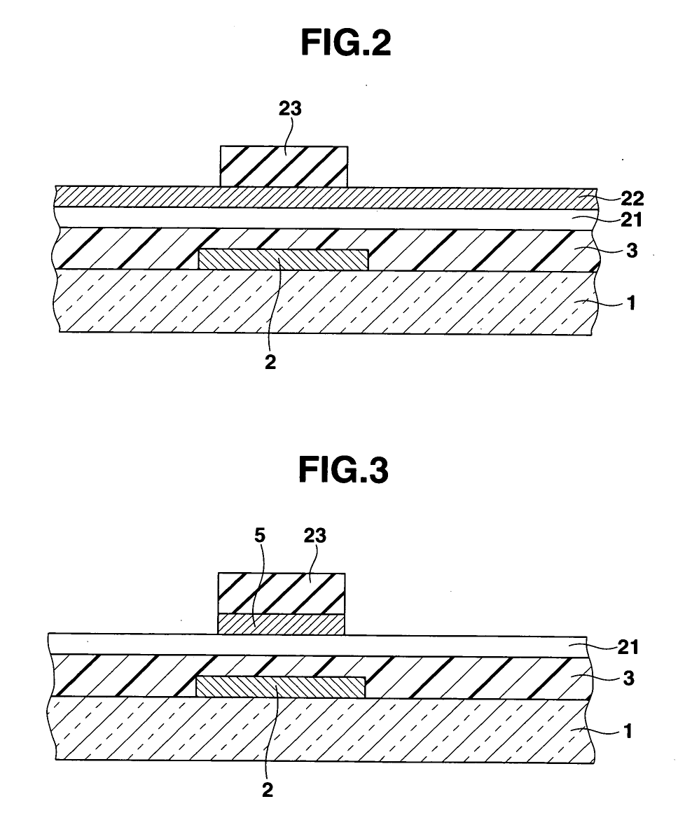

Next, one example of a method of manufacturing the thin film transistor panel described above is explained. First, as shown in FIG. 2, a metal film made of, for example, chromium which has been formed on the upper surface of the glass substrate 1 by a sputter method, is patterned by a photolithographic method to form the gate electrodes 2.

Then, the gate insulating film 3 made of silicon nitride, an intrinsic amorphous silicon film (semiconductor thin film formation film) 21 and a silicon nitride film (channel protective film formation film) 22 are sequentially formed, by a plasma CVD method, on the upper surfaces of the glass substrate 1 and the gate electrodes 2. Further, a resist film is applied to a channel protective film formation region on the upper surface of the silicon nitride film 22 by, for example, a printing method, and this resist film is patterned by the photolithographic method to form resist films 23 each of which is positioned above the gate electrode 2.

Then, the silicon nitride film 22 is subjected to dry etching as described later using the resist film 23 as a mask, so that parts of the silicon nitride film 22 except for a part in the region under the resist film 23 are removed, so that the channel protective film 5 is formed under the resist film 23, as shown in FIG. 3. Further, the resist film 23 is removed.

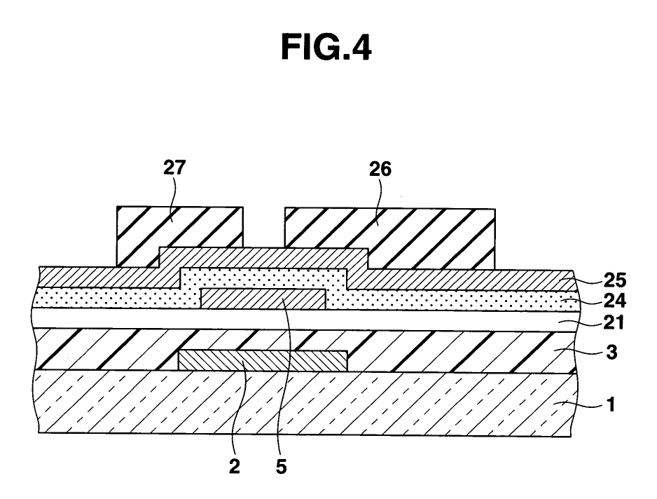

Then, as shown in FIG. 4, an n-type amorphous silicon film (ohmic contact layer formation film) 24 is formed on the upper surfaces of the channel protective films 5 and the intrinsic amorphous silicon film 21 by the plasma CVD method. A source/drain electrode formation film 25 made of, for example, chromium is entirely formed on the upper surface of the amorphous silicon film 24 by the sputter method.

A resist film is formed on the upper surface of the source/drain electrode formation film 25, by, for example, printing, and then this resist film is patterned by the photolithographic method to form resist films 26, 27 to source electrode and drain electrode formation regions separate from each other.

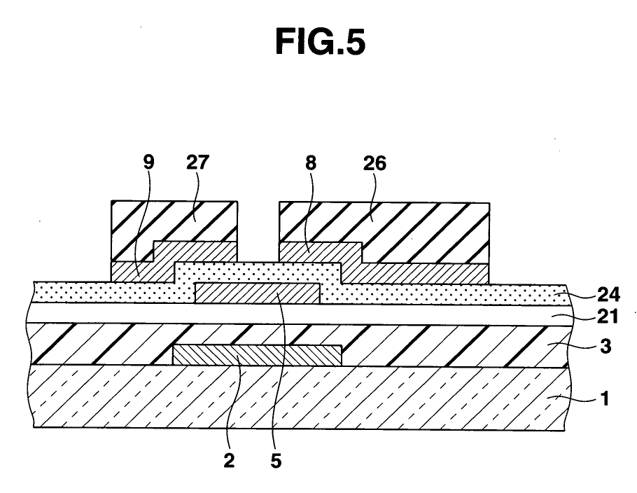

Then, exposed parts of the source/drain electrode formation film 25 are subjected to wet etching, using the resist films 26, 27 as masks to remove parts of the source/drain electrode formation film 25 except for parts under the resist films 26, 27. Thus, the source electrodes 8 and the drain electrodes 9 are formed under the resist films 26, 27, as shown in FIG. 5.

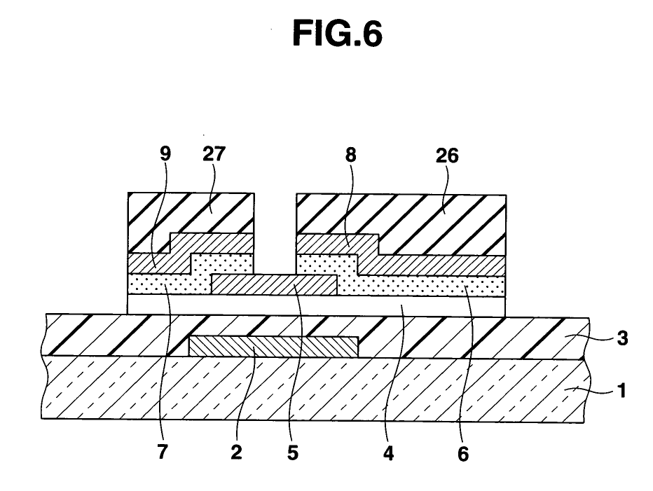

Then, the n-type amorphous silicon film 24 and the intrinsic amorphous silicon film 21 are sequentially subjected to dry etching using the resist films 26, 27 and the channel protective films 5 as masks to remove parts of the n-type amorphous silicon film 24 except for parts in the regions under the resist films 26, 27 and to remove parts of the intrinsic amorphous silicon film 21 except for parts in the regions under the resist films 26, 27 and the channel protective film 5. Consequently, as shown in FIG. 6, the ohmic contact layers 6, 7 are formed under the source electrodes 8 and the drain electrodes 9, and the semiconductor thin films 4 are formed under the ohmic contact layers 6, 7 and the channel protective films 5. Further, the resist films 26, 27 are removed.

Then, as shown in FIG. 1, the overcoat film 11 made of silicon nitride is formed on the upper surfaces of the thin film transistors 10 and the gate insulating film 3 by the plasma CVD method. Further, the contact holes 12 are formed in predetermined places of the overcoat film 11 by the photolithographic method.

Then, an ITO film is formed on the upper surface of the overcoat film 11 by the sputter method, and this ITO film is patterned by the photolithographic method, thereby forming the pixel electrodes 13 so that each of the pixel electrodes 13 is electrically connected to the source electrode 8 via the contact hole 12. Thus, the thin film transistor panel a part of which is shown in FIG. 1 can be obtained.

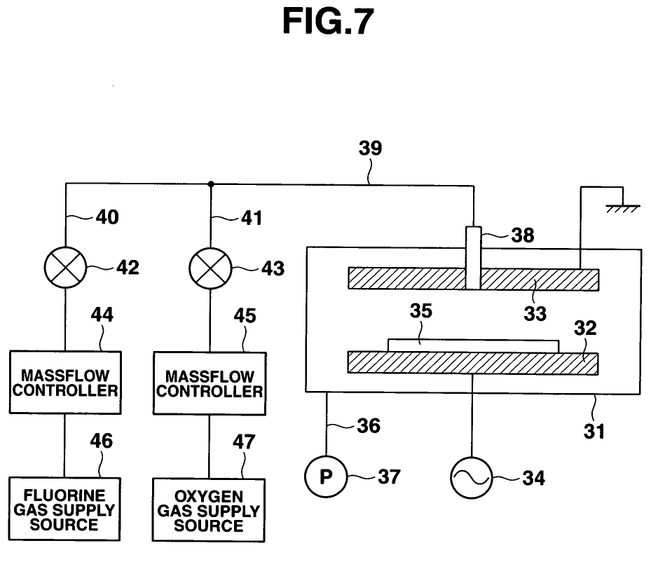

Next, one example of a reactive ion etching (RIE) apparatus for performing the dry etching in the manufacturing method described above is explained with reference to a schematic configuration diagram shown in FIG. 7. This RIE apparatus is a parallel plate type, and comprises a reaction container or chamber 31. A high-frequency electrode or pedestal 32 is provided in the lower part within the reaction container 31, and an opposite electrode or shower head 33 is provided in the upper part to face the high-frequency electrode 32. The high-frequency electrode 32 is electrically connected to a high-frequency power source 34, and the opposite electrode 33 is grounded. A processing target material 35 is mounted on the upper surface of the high-frequency electrode 32. A predetermined place of the lower part of the reaction container 31 is connected to a vacuum pump 37 via a pipe 36.

A gas introduction pipe 38 is provided in the center of the upper part of the reaction container 31 so that its one end penetrates through or extends into the center of the opposite electrode 33. The other end of the gas introduction pipe 38 is fluidly connected to a common pipe 39. First and second pipes 40, 41 are connected to the common pipe 39. The first and second pipes 40, 41 are provided with first and second electromagnetic valves 42, 43 and first and second massflow controllers 44, 45, respectively. A fluorine gas (F₂) supply source 46 and an oxygen gas (O₂) supply source 47 configured by, for example, cylinders are connected to the tips of the first and second pipes 40, 41, respectively.

Next, a case is described where the RIE apparatus having the configuration described above is used to perform the dry etching of the silicon nitride film 22 on the intrinsic amorphous silicon film 21 when the processing target material 35 mounted on the upper surface of the high-frequency electrode 32 is in a state shown in FIG. 2. First, the vacuum pump 37 is driven to discharge the gas in the reaction chamber 31, such that the pressure in the chamber 31 is reduced to 10 Pa.

Then, the first and second electromagnetic valves 42, 43 are opened simultaneously or successively, and thus, a fluorine gas and an oxygen gas are supplied from the fluorine gas supply source 46 and the oxygen gas supply source 47 to the common pipe 39. Consequently, a mixed gas of the fluorine and oxygen gases is introduced from the common pipe 39 into the reaction container 31 through the gas introduction pipe 38. In this case, the flow volumes of the fluorine gas and the oxygen gas are adjusted by the first and second massflow controllers 44, 45, such that the flow volume of the fluorine gas (F₂) is 100 sccm and the flow volume of the oxygen gas (O₂) is 100 to 400 sccm. Moreover, a high-frequency power of 700W at 13.56 MHz is applied to the high-frequency electrode 32 from the high-frequency power source 34.

Thus, the silicon nitride film 22 except for the region under the resist film 23 is subjected to dry etching and removed, where the etching rate is about 2000 Å/min. In this case, if the exposed part of the silicon nitride film 22 is completely removed, the lower intrinsic amorphous silicon film 21 is partially exposed, and the exposed part of the intrinsic amorphous silicon film 21 is subjected to the dry etching to a certain degree and removed, where the etching rate is about 400 Å/min. Therefore, the selectivity in this case is about five times, which is practical. Moreover, the global warming potential of the fluorine gas is zero, which can make a great contribution to the reduction of greenhouse gas emissions.

The fluorine gas supply source 46 may supply a fluorine gas diluted with one or a plurality of inert gases such as nitrogen, helium, neon and argon. For example, the flow volume of a fluorine gas diluted with a nitrogen gas at 20 vol % may be 500 sccm (the flow volume of the fluorine gas alone is 100 sccm), and the flow volume of an oxygen gas may be 100 to 400 sccm.

Furthermore, an inert gas supply source may be provided separately from the fluorine gas supply source 46 so that the mix gas may include an inert gas. Moreover, in each of the cases described above, the ratio of the flow volume of the oxygen gas to that of the fluorine gas is 1 to 4, but has only to be within 0.5 to 20. Further, the pressure in the reaction container 31 has only to be within 1 to 100 Pa.

Still further, the present invention is not limited to the embodiment described above, and modifications and improvements can be freely made without departing from the spirit of the invention.

What is claimed is:

1. A silicon nitride film dry etching method comprising subjecting a silicon nitride film to dry etching by reactive ion etching using a mixed gas including a fluorine gas and an oxygen gas.

2. The silicon nitride film dry etching method according to claim 1, wherein the silicon nitride film is formed on an amorphous silicon film.

3. The silicon nitride film dry etching method according to claim 1, wherein the mixed gas further includes an inert gas.

4. The silicon nitride film dry etching method according to claim 2, wherein the mixed gas further includes an inert gas.

5. The silicon nitride film dry etching method according to claim 1, wherein the ratio of the flow volume of the oxygen gas to that of the fluorine gas is 0.5 to 20.

6. The silicon nitride film dry etching method according to claim 2, wherein the ratio of the flow volume of the oxygen gas to that of the fluorine gas is 0.5 to 20.

7. The silicon nitride film dry etching method according to claim 3, wherein the ratio of the flow volume of the oxygen gas to that of the fluorine gas is 0.5 to 20.

8. The silicon nitride film dry etching method according to claim 4, wherein the ratio of the flow volume of the oxygen gas to that of the fluorine gas is 0.5 to 20.

9. The silicon nitride film dry etching method according to claim 1, wherein the ratio of the flow volume of the oxygen gas to that of the fluorine gas is 1 to 4.

10. The silicon nitride film dry etching method according to claim 2, wherein the ratio of the flow volume of the oxygen gas to that of the fluorine gas is 1 to 4.

11. The silicon nitride film dry etching method according to claim 3, wherein the ratio of the flow volume of the oxygen gas to that of the fluorine gas is 1 to 4.

12. The silicon nitride film dry etching method according to claim 4, wherein the ratio of the flow volume of the oxygen gas to that of the fluorine gas is 1 to 4.

13. The silicon nitride film dry etching method according to claim 1, wherein the dry etching is performed under a vacuum atmosphere at 1 to 100 Pa.

14. A silicon nitride film dry etching method comprising:
preparing a processing target material in which a silicon nitride film is provided on a substrate;
carrying the processing target material into a reaction chamber of a parallel plate type dry etching apparatus in which a high-frequency electrode and an opposite electrode are arranged in parallel with each other, and mounting the substrate of the processing target material on the high-frequency electrode;
reducing the pressure in the reaction chamber, and introducing a fluorine gas and an oxygen gas into the reaction chamber; and
applying high-frequency waves to the high-frequency electrode, and etching the silicon nitride film.

15. The silicon nitride film dry etching method according to claim 14, wherein preparing the processing target material in which the silicon nitride film is provided on the substrate includes forming an intrinsic amorphous silicon film on the substrate, and forming a processing target material made of the silicon nitride film on the intrinsic amorphous silicon film.

16. The silicon nitride film dry etching method according to claim 14, wherein the fluorine gas is used after diluted with an inert gas.

17. The silicon nitride film dry etching method according to claim 14, wherein the ratio of the flow volume of the oxygen gas to that of the fluorine gas is 0.5 to 20.

18. The silicon nitride film dry etching method according to claim 16, wherein the ratio of the flow volume of the oxygen gas to that of the fluorine gas is 0.5 to 20.

19. The silicon nitride film dry etching method according to claim 14, wherein the ratio of the flow volume of the oxygen gas to that of the fluorine gas is 1 to 4.

20. The silicon nitride film dry etching method according to claim 16, wherein the ratio of the flow volume of the oxygen gas to that of the fluorine gas is 1 to 4.

21. The silicon nitride film dry etching method according to claim 14, wherein the dry etching is performed under a vacuum atmosphere at 1 to 100 Pa.

22. A silicon nitride film dry etching method comprising subjecting a silicon nitride film to dry etching by reactive ion etching using a mixed gas essentially consisting of a fluorine gas and an oxygen gas, or a mixed gas essentially consisting of a fluorine gas, an oxygen gas and an inert gas.
